(19) United States
(12) Patent Application Publication
(10) Pub. No.: US 2026/0309813 A1
(43) Pub. Date: Oct. 8, 2026

(54) FUNCTION ESTIMATION PROTOCOLS WITH PHOTONIC SENSORS

(71) Applicant: Government of the United States of America, as represented by the Secretary of Commerce, Gaithersburg, MD (US)

(72) Inventors: Alexey Vyacheslavovich Gorshkov, Potomac, MD (US); Jacob Allen Bringewatt, Rockville, MD (US); Adam Ethan Ehrenberg, Atlanta, GA (US); Tarushii Goel, McLean, VA (US)

(21) Appl. No.: 19/463,776

(22) Filed: Jan. 29, 2026

Related U.S. Application Data
(60) Provisional application No. 63/751,080, filed on Jan. 29, 2025.

(51) Int. Cl. G01R 33/032

(52) U.S. Cl. CPC G01R 33/032

(57) ABSTRACT

A photonic quantum sensor network includes a plurality of optical modes coupled to a set of local physical parameters, wherein the optical modes include a subset of positive modes associated with positive coefficients of a linear function and a subset of negative modes associated with negative coefficients. A state preparation assembly generates a photonic probe state comprising a superposition of a first branch having a fixed total photon number distributed among the positive modes and a second branch having the fixed total photon number distributed among the negative modes and a reference mode. A control assembly applies a sequence of unitary operations to the photonic probe state between passes through the optical modes to coherently map the photonic probe state between different vector configurations selected from a set of integer vectors to preserve a relative phase. A detection assembly measures the relative phase accumulated on the photonic probe state.

### CROSS-REFERENCE TO RELATED APPLICATION

This application claims the benefit of U.S. Provisional Patent Application Ser. No. 63/751,080 (filed Jan. 29, 2025), which is herein incorporated by reference in its entirety.

### STATEMENT REGARDING FEDERALLY SPONSORED RESEARCH

This invention was made with United States Government support from the National Institute of Standards and Technology (NIST), an agency of the United States Department of Commerce. The Government has certain rights in this invention.

### BACKGROUND

The present invention generally relates to the field of quantum metrology and distributed photonic sensor networks, and more particularly to techniques for implementing optimal function estimation protocols that leverage entangled states of light and coherent control operations to ascertain linear combinations of local phase shifts or displacements with Heisenberg-scaling precision.

Quantum metrology exploits non-classical features of quantum mechanics, such as entanglement and squeezing, to enhance the precision of parameter estimation beyond the standard quantum limit achievable with classical resources. Within this domain, distributed quantum sensing has emerged as a significant area of research, where the simultaneous estimation of multiple parameters or functions thereof, such as the average of spatially distributed fields, is required. The theoretical framework for optimizing measuring analytic functions of unknown local parameters coupled to qubit sensors is relatively well-developed, offering rigorous bounds and explicit protocols for applications ranging from field interpolation to noise characterization. These qubit-based models rely on parallel resources, where all parameters can theoretically be measured simultaneously to maximal precision, a paradigm that has driven substantial progress in the fundamental understanding of quantum sensor networks.

Despite these advances in qubit systems, the translation of these optimal protocols to photonic architectures, such as networks of Mach-Zehnder interferometers or microwave resonator arrays, remains incomplete. While extensive theoretical and experimental work exists regarding photonic quantum sensors, the rigorous asymptotic performance limits for estimating arbitrary linear functions of local phase shifts or quadrature displacements have not been fully established. Existing photonic protocols often predominately utilize Gaussian probe states, such as squeezed vacuum states, which, while effective for certain tasks like displacement sensing under average photon number constraints, do not necessarily represent the information-theoretic optimum for all sensing scenarios, particularly those involving phase sensing subject to strict photon number constraints. Furthermore, the discrete nature of photonic resources, which must often be distributed sequentially or physically divided among modes in a zero-sum manner, presents theoretical challenges that prevent a direct mapping of known qubit protocols to the photonic domain.

Current methodologies for function estimation in photonic networks frequently lack a generalized framework capable of deriving optimal probe states and control sequences for arbitrary linear functions, especially those involving complex combinations of positive and negative coefficients. The absence of a unified algebraic approach for generating optimal protocols limits the ability to design sensor networks that achieve the ultimate precision allowed by quantum mechanics, the Heisenberg scaling, under experimentally relevant constraints such as limited entanglement or discrete control operations. Consequently, there is a need for rigorous lower bounds on the achievable mean square error in these specific photonic contexts and for the identification of concrete protocols, beyond standard Gaussian approaches, that can saturate these bounds through specific manipulations of entangled states like weighted N00N states.

It is therefore an objective of the present invention to provide systems and methods for configuring photonic quantum sensor networks that utilize coherent switching between parameterized families of entangled probe states to estimate linear functions of physical parameters with optimal precision, thereby overcoming the above-mentioned disadvantages of the prior art at least in part. Accordingly, methods and equipment for using photonic materials involving optical resonator technology and interferometric networks to measure spatially varying fields would be advantageous and would be favorably received in the art.

### BRIEF DESCRIPTION

One aspect of the present invention relates to a photonic quantum sensor network. A photonic quantum sensor network may be understood as a distributed architecture of optical pathways and components configured to leverage non-classical properties of light, such as entanglement and superposition, to estimate physical quantities with precision that surpasses standard classical limits.

It may be provided that the network comprises a plurality of optical modes coupled to a set of local physical parameters, wherein the plurality of optical modes includes a subset of positive modes associated with positive coefficients of a linear function and a subset of negative modes associated with negative coefficients of the linear function. Optical modes generally refer to distinct, orthogonal states of the electromagnetic field, such as separate spatial paths or frequency bins, while the local physical parameters represent the specific scalar values, such as phase shifts, impressed upon those modes by the environment. This arrangement allows the hardware to physically embody the mathematical structure of the linear function to be estimated, segregating the optical paths based on the sign of their contribution to the target value. One technical advantage of this configuration is the improved functionality in directly sensing arbitrary linear combinations of parameters, such as gradients or weighted averages, without the need for individual parameter estimation followed by classical post-processing, thereby reducing computational overhead and minimizing error propagation.

It may be provided that a state preparation assembly is arranged to generate a photonic probe state, wherein the photonic probe state comprises a superposition of a first branch having a fixed total photon number N distributed among the positive modes and zero photons in the negative modes, and a second branch having zero photons in the positive modes and the fixed total photon number N distributed among the negative modes and a reference mode. A state preparation assembly involves the optical hardware, such as nonlinear crystals or superconducting circuits, necessary to initialize the system in a specific quantum state. The described probe state represents a macroscopic superposition where the entire energy of the system is delocalized between disjoint sets of modes. This arrangement provides the advantage of maximizing the sensitivity of the probe to the differential phase accumulation dictated by the linear function, effectively establishing a resource state capable of achieving Heisenberg-limited precision. By ensuring the total photon number is fixed and concentrated in specific branches, this arrangement enhances performance by eliminating shot noise associated with vacuum fluctuations in unused modes.

It may be provided that a control assembly is arranged to apply a sequence of unitary operations to the photonic probe state between a plurality of passes through the plurality of optical modes, wherein the control assembly coherently maps the photonic probe state between different vector configurations selected from a set of integer vectors to preserve a relative phase between the first branch and the second branch. Unitary operations are reversible transformations that preserve the norm and quantum information of the state, while coherent mapping ensures that the phase relationship between the superposition branches remains intact during transformations. This arrangement facilitates the implementation of multi-step interrogation protocols where the sensitivity of the probe is dynamically adjusted between passes. One advantage of this control mechanism is the novelty of distributing the sensing resources across time steps to satisfy optimal sensing conditions that might otherwise require prohibitively large amounts of simultaneous entanglement, thereby optimizing the utility of the available quantum hardware.

It may be provided that a detection assembly is arranged to measure the relative phase accumulated on the photonic probe state after the plurality of passes. A detection assembly typically includes devices such as photon number resolving detectors or homodyne setups designed to project the final quantum state onto a measurable basis. The relative phase serves as the analog encoding of the linear function's value. This arrangement ensures that the information encoded during the interaction with the physical parameters is faithfully retrieved. One technical advantage is the enhanced accuracy of the measurement, as the accumulated signal reflects the coherent integration of the parameter interactions over the entire protocol, allowing for the extraction of the target function value with a precision scaling superior to classical strategies.

One aspect of the present invention relates to a method for operating a quantum sensor network to estimate a linear function of a set of local physical parameters. This method may be understood as an algorithmic procedure for orchestrating the preparation, evolution, and measurement of quantum optical states within a distributed sensing architecture to ascertain a specific weighted combination of physical quantities, such as phase shifts or field amplitudes, with information-theoretic optimality.

It may be provided that the method involves identifying a set of integer vectors, wherein each vector in the set of integer vectors defines a photon number distribution satisfying a norm constraint relative to a fixed total photon number distributed across a plurality of optical modes. Integer vectors in this context represent discrete configurations of photon occupancy across the various sensors, effectively defining the shape of the probe state in the Fock basis, while the norm constraint ensures that the total energy resources remain constant and physically realizable. One technical advantage of this step is the improved functionality in resource allocation, as it mathematically delineates the complete subspace of valid quantum states that can be utilized to interrogate the parameters, ensuring that the subsequent protocol design is strictly bounded by the available photon number resources.

It may be provided that the method includes calculating a protocol vector comprising non-negative integers that satisfy a linear Diophantine equation relating a matrix formed from the set of integer vectors to a vector of rational coefficients representing the linear function. A protocol vector serves as a temporal blueprint, dictating the duration or number of passes for which each specific photon configuration is employed, while the linear Diophantine equation embodies the condition for optimal sensitivity matching between the probe's evolution and the target function. This arrangement provides the enhanced performance of ensuring that the cumulative phase accumulated by the system exactly aligns with the desired linear combination of parameters, thereby enabling the method to mathematically guarantee the saturation of the quantum Cramér-Rao bound.

It may be provided that the method proceeds by generating a photonic probe state initialized in a superposition of a first branch and a second branch according to a first vector selected from the set of integer vectors. This generation step involves physically creating a quantum state where the system exists simultaneously in two distinct macroscopic configurations defined by the selected vector. One advantage of this initialization is the novelty of preparing a generalized N00N state that is specifically tailored to the first stage of the sensing protocol, establishing a coherently coupled baseline from which differential phase information can be accumulated with Heisenberg-limited sensitivity.

It may be provided that the method involves encoding the set of local physical parameters into the photonic probe state by subjecting the photonic probe state to a sequence of passes through the plurality of optical modes. Encoding refers to the unitary process where the unknown physical values are imprinted onto the quantum phases of the optical modes. This arrangement allows for the sequential accumulation of signal, which is technically advantageous because it amplifies the phase signature relative to the quantum noise floor, effectively trading time resources for enhanced signal-to-noise ratio in a manner that scales favorably with the number of passes.

It may be provided that a control unitary operation is applied to the photonic probe state between the passes to coherently switch the photonic probe state from the first vector to a subsequent vector selected from the set of integer vectors based on the protocol vector, wherein the control unitary operation maintains the relative phase between the first branch and the second branch. Coherent switching implies transforming the photon number distribution, and thus the local sensitivity of the probe, without collapsing the superposition or destroying the phase information gathered in previous steps. One technical advantage of this dynamic reconfiguration is the utility of synthesizing a complex effective Hamiltonian over time; by varying the probe state between passes, the method can construct an optimal measurement operator that might otherwise require complex, simultaneous multi-mode entanglement that is physically intractable, thus enabling optimal sensing with reduced instantaneous hardware complexity.

It may be provided that the method includes detecting the relative phase accumulated on the photonic probe state after a total number of passes defined by the protocol vector. Detecting involves the physical measurement process that collapses the quantum state to yield a classical estimate of the phase difference between the superposition branches. This step provides the advantage of improved accuracy, as the final measurement extracts the aggregate result of the intelligently designed evolution path, yielding an estimate of the linear function that exhibits the minimum possible mean square error allowed by the laws of quantum mechanics.

### BRIEF DESCRIPTION OF THE DRAWINGS

The following description cannot be considered limiting in any way. Various objectives, features, and advantages of the disclosed subject matter can be more fully appreciated with reference to the following detailed description of the disclosed subject matter when considered in connection with the following drawings, in which like reference numerals identify like elements.

FIG. 1 shows, according to some embodiments, a schematic block diagram of a photonic quantum sensor network arranged to estimate a linear function of spatially distributed physical parameters.

FIG. 2 shows, according to some embodiments, a detailed architectural diagram of the sensor network illustrating the coupling between the state preparation assembly, the positive and negative optical modes, the control assembly, and the detection assembly.

FIG. 3 shows, according to some embodiments, a schematic representation of a specific physical implementation utilizing a network of Mach-Zehnder interferometers to measure optical path length variations.

FIG. 4 shows, according to some embodiments, a schematic representation of an alternative physical implementation utilizing a plurality of microwave resonators coupled to a superconducting qubit circuit and a SQUID array for magnetoencephalography applications.

FIG. 5 shows, according to some embodiments, a conceptual diagram illustrating the parameterized families of probe states defined by the set of integer vectors and the coherent mapping trajectories dictated by the protocol vector.

FIG. 6 shows, according to some embodiments, a flowchart illustrating the method for operating the quantum sensor network to solve the linear Diophantine equation and execute the sensing protocol.

FIG. 7 shows, according to some embodiments, a comparative performance graph plotting the mean square error against photon number, demonstrating the Heisenberg scaling advantage of the disclosed protocols over separable bounds.

FIG. 8 shows, according to some embodiments, a computational and control system to control the network, acquire data, and analyze data for function optimalization using photon sensors.

### DETAILED DESCRIPTION

A detailed description of one or more embodiments is presented herein by way of exemplification and not limitation.

Conventional approaches to distributed quantum sensing have largely bifurcated into two distinct theoretical regimes: qubit-based sensor networks, where resources are effectively parallelizable allowing simultaneous maximal sensitivity to all parameters, and photonic sensor networks, where resources must be physically distributed in a zero-sum manner among various modes. While the asymptotic performance limits for qubit sensors are rigorously established, the corresponding ultimate bounds for photonic systems, particularly for estimating arbitrary linear functions of local phase shifts beyond simple averages, have remained elusive or constrained to specific Gaussian state ansatzes such as squeezed vacuum states. A significant deficiency in the prior art lies in the reliance on separable protocols or restricted entanglement schemes that fail to exploit the full Hilbert space available under strict photon number constraints, thereby limiting achievable precision to the Standard Quantum Limit (scaling as the inverse square root of photon number) rather than the fundamental Heisenberg limit (scaling as the inverse of photon number) allowed by quantum mechanics. Furthermore, existing methodologies often lack a unified algebraic framework capable of deriving optimal control sequences for functions with mixed positive and negative coefficients, necessitating ad hoc protocol design rather than systematic generation.

The photonic quantum sensor network described herein overcomes these deficiencies by implementing a hardware architecture that explicitly creates and manipulates a parameterized family of macroscopic superposition states specifically tailored to the algebraic structure of the target linear function. By structurally differentiating between optical modes associated with positive and negative coefficients and utilizing a state preparation assembly capable of generating generalized N00N-like states, the system circumvents the limitations of Gaussian-only approaches. Unlike conventional systems that may rely on static entanglement resources, the disclosed network integrates a control assembly that applies unitary operations between sequential passes, effectively synthesizing a dynamic measurement operator that accumulates the precise linear combination of phases required to saturate the quantum Cramér-Rao bound.

It has been discovered that the information-theoretic optimality of a photonic protocol for function estimation is governed by a specific algebraic condition wherein the quantum Fisher information matrix, when acted upon by a dual basis vector, yields a result proportional to the target function coefficient vector. This discovery translates the complex physical problem of optimal sensing into a solvable linear Diophantine equation relating a matrix of integer vectors, representing available photon number distributions, to the rational coefficients of the parameter function. Consequently, an optimal sensing strategy does not merely require entanglement, but specifically requires the probe state to oscillate coherently between distinct vector configurations in a sequence defined by the integer solution to this equation.

The technical advantages of this arrangement are manifold and significant. By enabling the protocol to saturate the Heisenberg limit for arbitrary linear functions, the photonic quantum sensor network achieves a measurement variance scaling of 1/N², providing a quadratic reduction in the number of photons required to achieve a target precision compared to separable strategies. This improved functionality is particularly advantageous in applications such as biological sensing or gravitational field mapping where the probe energy must be minimized to avoid damaging the sample or disturbing the system under test. Furthermore, the utilization of sequential passes and coherent switching allows the system to effectively trade time resources for complexity, enabling high-precision estimation with lower instantaneous entanglement requirements than would be necessary in a single-shot, spatially parallelized architecture.

In an embodiment, a photonic quantum sensor network (200) comprises a plurality of optical modes (202) coupled to a set of local physical parameters (204), wherein the plurality of optical modes (202) includes a subset of positive modes (206) associated with positive coefficients of a linear function and a subset of negative modes (208) associated with negative coefficients of the linear function; a state preparation assembly (210) arranged to generate a photonic probe state (212), wherein the photonic probe state (212) comprises a superposition of a first branch having a fixed total photon number N distributed among the positive modes (206) and zero photons in the negative modes (208), and a second branch having zero photons in the positive modes (206) and the fixed total photon number N distributed among the negative modes (208) and a reference mode (214); a control assembly (216) arranged to apply a sequence of unitary operations (218) to the photonic probe state (212) between a plurality of passes through the plurality of optical modes (202), wherein the control assembly (216) coherently maps the photonic probe state (212) between different vector configurations selected from a set of integer vectors W to preserve a relative phase between the first branch and the second branch; and a detection assembly (220) arranged to measure the relative phase accumulated on the photonic probe state (212) after the plurality of passes. In an embodiment, the set of integer vectors W comprises vectors ωsatisfying a condition ∥ω∥_{1,P}=N and ∥ω∥_{1,N}≤N, wherein P denotes indices of the positive modes (206) and N denotes indices of the negative modes (208). In an embodiment, the control assembly (216) comprises a memory storing a protocol vector r that satisfies a linear Diophantine equation Wr=NMα/∥α∥_{1,P}, wherein W is a matrix having columns from the set of integer vectors W, M is a total number of the passes, and α is a vector of rational coefficients defining the linear function. In an embodiment, the photonic probe state (212) generated by the state preparation assembly (210) for a specific integer vector ω corresponds to a superposition form ω□_{P} [symbol] v0 [symbol] +e^{iφ}v−ω□_{N} [symbol] |N−∥ω|N∥1 [symbol] , wherein φ is an arbitrary phase. In an embodiment, the plurality of optical modes (202) comprises a network of Mach-Zehnder interferometers (222). In an embodiment, the plurality of optical modes (202) comprises a plurality of microwave resonators (224) and the state preparation assembly (210) comprises a superconducting qubit circuit (226) coupled to the plurality of microwave resonators (224). In an embodiment, the set of local physical parameters (204) comprises magnetic fluxes generated by electrical activity in a biological source and coupled to the plurality of microwave resonators (224) via a superconducting quantum interference device array (228). In an embodiment, the control assembly (216) applies the sequence of unitary operations (218) at discrete time intervals corresponding to the plurality of passes. In an embodiment, the detection assembly (220) comprises a photon number resolving detector (230) arranged to perform a parity measurement on the photonic probe state (212). In an embodiment, the control assembly (216) comprises an optical switch loop (232) arranged to recirculate the photonic probe state (212) through the plurality of optical modes (202) for the plurality of passes.

The photonic quantum sensor network (200) serves as the foundational hardware architecture for implementing optimal function estimation protocols, integrating optical, control, and detection subsystems to exploit the full computational potential of the Hilbert space available to bosonic modes. At the core of the system lies a plurality of optical modes (202) that are physically coupled to a set of local physical parameters (204), which represent the unknown scalar quantities, such as phase shifts θⱼ or displacements, that the system seeks to estimate as a linear combination q=α·θ. The physical implementation of these modes (202) varies based on the specific sensing application, ranging from spatial paths in an interferometric array to distinct frequency modes in a microwave cavity, but in all variations, they function as the quantum registers upon which the environmental parameters are imprinted via a Hamiltonian interaction Ĥ=θ·ĝ. A distinguishing feature of this arrangement is the logical and physical segregation of these modes into a subset of positive modes (206) corresponding to indices where the linear function coefficients are non-negative (αⱼ≥0) and a subset of negative modes (208) where coefficients are negative (αⱼ<0). This bifurcation allows the network to physically encode the signed arithmetic of the target function into the photon distribution itself, enabling the direct estimation of differences or gradients without the noise penalty associated with independent measurements.

To interrogate these modes, the system employs a state preparation assembly (210) specifically calibrated to generate a photonic probe state (212) that exhibits a precise macroscopic superposition structure capable of saturating the Heisenberg limit. Functionally, this probe state (212) is constructed as a superposition of two distinct branches, namely, a first branch where a fixed total photon number N is distributed exclusively among the positive modes (206) (with the negative modes (208) remaining in a vacuum state), and a second branch where the positive modes (206) are empty and the N photons are distributed among the negative modes (208) and, if necessary, an auxiliary reference mode (214). This specific “generalized N00N” structure maximizes the variance of the generator of translations with respect to the parameter of interest, thereby maximizing the quantum Fisher information. In implementations involving microwave frequencies, the state preparation assembly (210) may utilize superconducting qubits interacting with resonators to synthesize these non-classical Fock state superpositions via Jaynes-Cummings interactions, whereas optical implementations might utilize non-linear crystals and post-selection or advanced squeezing and displacement techniques.

Crucial to the operation of the network is the control assembly (216), which orchestrates the time-evolution of the probe state (212) beyond simple static interrogation. The control assembly (216) applies a sequence of unitary operations (218) between sequential passes through the optical modes (202), effectively acting as a quantum logic gate array that modifies the probe's sensitivity profile dynamically. By coherently mapping the photonic probe state (212) between different vector configurations selected from a specific set of integer vectors W, the control assembly (216) ensures that the relative phase accumulated between the two branches of the superposition exactly matches the desired linear combination of parameters after the total sensing time. This coherent mapping capability is technically significant because it allows the system to synthesize a complex measurement operator from simpler, discrete interactions, thereby circumventing the need for simultaneous entanglement across all modes which scales unfavorably with system size. The sequence of operations (218) ensures that the first branch of the superposition is mapped to the first branch of the subsequent configuration, and the second branch to the second branch, preserving the delicate phase information encoding the parameter values.

Finally, the detection assembly (220) is arranged to measure the relative phase accumulated on the photonic probe state (212) after the complete sequence of passes. The functionality of the detection assembly (220) is to project the final quantum state, which encodes the value Wr·θ in its phase φₜₒₜ, onto a measurable basis that allows for the extraction of this phase with high sensitivity. In preferred embodiments, this involves a parity measurement, which is known to saturate the quantum Cramér-Rao bound for N00N-like states. By integrating photon number resolving detectors or performing state tomography facilitated by the same control hardware used for state preparation (e.g., qubit-assisted readout), the detection assembly (220) converts the quantum advantage into a classical estimator. The benefit of this integrated hardware system is the realization of a sensor that achieves a mean square error scaling of 1/N² for arbitrary linear functions, a quadratic improvement over classical separable strategies that scale as 1/N.

In certain embodiments, the functionality of the control assembly (216) is governed by a precise mathematical framework wherein the set of integer vectors W (234) defines the permissible configurations of the photonic probe state (212) during any given pass. Each vector ω within this set corresponds to a specific distribution of the fixed total photon number N across the sensor array, subject to the strict physical constraint that the 1-norm of the vector restricted to the positive modes (206), denoted as ∥ω∥_{1,P}, must exactly equal N. This condition ensures that the first branch of the macroscopic superposition always utilizes the full energy resources available to the system, thereby maximizing the phase sensitivity relative to the positive coefficients of the linear function. Furthermore, the vectors must satisfy the condition that the 1-norm restricted to the negative modes (208) is less than or equal to N, with any deficit in photon number being allocated to an auxiliary reference mode (214), thus maintaining the coherence of the superposition while accommodating the signed arithmetic of the target function.

To operationalize these state configurations, the control assembly (216) utilizes a memory module storing a protocol vector r (236), which represents the solution to a linear Diophantine equation Wr=NMα/∥α∥_{1,P}. Here, the matrix W is constructed from the permissible integer vectors W as columns, and the vector r dictates the integer number of passes for which each specific probe configuration is employed. The technical benefit of deriving the control sequence from this specific algebraic relation is the guarantee that the total accumulated phase shift φₜₒₜ after M passes is exactly proportional to the target linear function q(θ), a necessary condition to saturate the Heisenberg limit for arbitrary coefficients. The photonic probe state (212) generated for a specific vector ω takes the form of a generalized N00N state ω□_{P} [symbol] v0 [symbol] +e^{iφ}v−ω□_{N} [symbol] |N−∥ω|N∥1 [symbol] , a structure that provides maximal variance in the generator of translations and thus maximal Fisher information.

Regarding physical implementations, the plurality of optical modes (202) may be realized as a network of Mach-Zehnder interferometers (222), where the local physical parameters (204) manifest as phase shifts induced by variations in optical path length due to phenomena such as gravitational forces acting on a cantilever or refractive index fluctuations. In alternative embodiments particularly suited for biological sensing, the optical modes (202) comprise microwave resonators (224) integrated into a superconducting circuit architecture. In this variation, the state preparation assembly (210) utilizes a superconducting qubit circuit (226) to mediate the generation of the Fock state superpositions via non-linear interactions, which is often experimentally more tractable than probabilistic optical generation. Furthermore, a superconducting quantum interference device (SQUID) array (228) may be coupled to the microwave resonators (224) to transduce magnetic fluxes, such as those generated by neuronal electrical activity in a magnetoencephalography context, into the resonance frequency shifts that constitute the local physical parameters (204).

The temporal operation of the network is characterized by the application of the unitary operations (218) at discrete time intervals, reflecting the practical constraints of pulsed control logic or the discrete nature of passing through physical interferometric elements. To efficiently utilize physical resources, the control assembly (216) may employ an optical switch loop (232) that recirculates the photonic probe state (212) through the same physical set of detectors for the required number of passes M, rather than requiring a cascaded chain of M physical interferometers. Upon completion of the sensing protocol, the detection assembly (220) employs a photon number resolving detector (230) to perform a parity measurement on the output state. This specific measurement basis is theoretically optimal for extracting the phase information encoded in N00N-like states, allowing the system to resolve the value of the linear function with a precision that scales inversely with the total number of photons used.

In an embodiment, the system implements a sensing protocol defined by a dynamic trajectory through the Hilbert space of the optical modes, wherein the photonic probe state is not maintained as a static resource but is instead coherently transformed between discrete vector configurations between sequential interactions with the physical parameters. Unlike systems utilizing static entanglement resources that remain fixed throughout the sensing duration, the disclosed configuration actively manipulates the photon number distribution, specifically shifting the N-photon occupancy among modes associated with different coefficients of the target linear function, while preserving the macroscopic superposition between the signal branches. This coherent switching mechanism allows the sensor network to synthesize an effective Hamiltonian that exactly matches the algebraic structure of the linear function being estimated, thereby accumulating a total phase shift that saturates the fundamental quantum precision limit without requiring the simultaneous hyper-entanglement of all sensing nodes.

Furthermore, the specific structural composition of the probe state utilized in these embodiments diverges from standard Gaussian or squeezed-state approaches by employing a superposition of Fock states where the total energy is strictly partitioned between modes corresponding to positive coefficients and modes corresponding to negative coefficients. This arrangement, often necessitating an auxiliary reference mode to balance photon number conservation when the coefficient norms differ, ensures that the variance of the generator of translations is maximized specifically for the target linear combination. The configuration of the control assembly is derived from the integer solution to a linear Diophantine equation relating the set of physically realizable photon distributions to the rational coefficients of the parameter function, a deterministic configuration method that guarantees the resulting hardware operations yield a measurement variance scaling as 1/N². This approach effectively converts the abstract problem of optimal estimator design into a concrete integer linear programming task that configures the physical control pulse sequence.

In an embodiment, a method for operating a quantum sensor network (200) to estimate a linear function of a set of local physical parameters (204) comprises identifying a set of integer vectors (234), wherein each vector in the set of integer vectors (234) defines a photon number distribution satisfying a norm constraint relative to a fixed total photon number distributed across a plurality of optical modes (202); calculating a protocol vector (236) comprising non-negative integers that satisfy a linear Diophantine equation relating a matrix formed from the set of integer vectors (234) to a vector of rational coefficients representing the linear function; generating a photonic probe state (212) initialized in a superposition of a first branch and a second branch according to a first vector selected from the set of integer vectors (234); encoding the set of local physical parameters (204) into the photonic probe state (212) by subjecting the photonic probe state (212) to a sequence of passes through the plurality of optical modes (202); applying a control unitary operation (218) to the photonic probe state (212) between the passes to coherently switch the photonic probe state (212) from the first vector to a subsequent vector selected from the set of integer vectors (234) based on the protocol vector (236), wherein the control unitary operation (218) maintains the relative phase between the first branch and the second branch; and detecting the relative phase accumulated on the photonic probe state (212) after a total number of passes defined by the protocol vector (236). In an embodiment, the identifying the set of integer vectors (234) comprises selecting vectors such that a 1-norm of restricted to a set of positive modes (206) equals the fixed total photon number, and a 1-norm of restricted to a set of negative modes (208) is less than or equal to the fixed total photon number. In an embodiment, the calculating the protocol vector (236) comprises solving the linear Diophantine equation, wherein is a 1-norm of the vector of rational coefficients restricted to positive coefficients. In an embodiment, the generating the photonic probe state (212) comprises preparing a superposition state of the form, wherein the first branch comprises photons in positive modes (206) and the second branch comprises photons in negative modes (208) and a reference mode (214). In an embodiment, the detecting the relative phase comprises performing a parity measurement on the photonic probe state (212) using a photon number resolving detector (230) coupled to the plurality of optical modes (202). In an embodiment, the set of local physical parameters (204) comprises a distribution of magnetic fluxes, and the plurality of optical modes (202) comprises microwave resonators (224) coupled to a superconducting quantum interference device array (228), and wherein the method estimates a location of electrical activity in a biological source. In an embodiment, the set of local physical parameters (204) comprises optical path lengths in a network of Mach-Zehnder interferometers (222), and wherein the method measures a spatial variation of a gravitational field acting on the network. In an embodiment, the applying the control unitary operation (218) utilizes a sequence of CNOT operations on a set of superconducting qubits (226) coupled to the plurality of optical modes (202) to map between Fock state superpositions. In an embodiment, the method further comprises iterating the generating, encoding, applying, and detecting steps for a plurality of repetitions to construct a statistical estimate of the linear function achieving a Heisenberg scaling precision limit. In an embodiment, the calculating the protocol vector (236) utilizes an integer linear programming algorithm to minimize the total number of passes required to satisfy the linear Diophantine equation.

The method for operating a quantum sensor network (200) initiates with the step of identifying a set of integer vectors (234), a process that establishes the boundary conditions for the system's Hilbert space exploration. Each vector within this set serves as a digital representation of a permissible physical configuration, defining a photon number distribution across the plurality of optical modes (202) that adheres to strict norm constraints relative to the fixed total photon number. By systematically explicitly constructing this set to include only those vectors where the photon count in positive-coefficient modes sums to, the method ensures that every subsequent operation operates within a subspace that is maximally sensitive to the constructive components of the linear function. This identification step provides the benefit of filtering the infinite possibilities of state space down to a tractable, optimal subset, thereby streamlining the computational overhead required for protocol design.

Following the definition of the state space, the method proceeds to calculating a protocol vector (236), which involves solving a linear Diophantine equation that fundamentally links the physical capabilities of the hardware (represented by the matrix of integer vectors) to the informational requirements of the sensing task (represented by the coefficient vector). This calculation is an algorithmic planning stage where the sequence and duration of each probe configuration are determined to ensure that the cumulative phase evolution of the system is exactly proportional to the target function. The implementation of this step, often utilizing integer linear programming techniques, offers the substantial benefit of mathematically guaranteeing optimality; it provides a certified recipe for achieving Heisenberg scaling that eliminates the need for heuristic or trial-and-error experimental design.

With the protocol established, the method involves generating a photonic probe state (212) initialized in a superposition according to the first vector selected from the set (234). This step translates the abstract integer vector into a physical reality, creating a coherent quantum state where the system exists simultaneously in two distinct macroscopic configurations of photon occupancy. This initialization is critical for establishing the interferometric baseline of the measurement, providing a resource state that is entangled in a manner specifically tailored to the start of the sensing sequence. The benefit of this targeted generation is a high-fidelity starting point that avoids the decoherence and fidelity losses associated with generic or approximate state preparation methods.

The core sensing interaction occurs during the step of encoding the set of local physical parameters (204) into the photonic probe state (212) by subjecting it to a sequence of passes through the plurality of optical modes (202). During each pass, the unknown environmental parameters, such as magnetic fluxes or gravitational phase shifts, are impressed upon the quantum phase of the probe state via the Hamiltonian interaction. This sequential encoding allows the signal to accumulate constructively over time, amplifying the phase difference between the superposition branches in direct proportion to the parameter values and the specific photon distribution active during that pass. This arrangement provides the advantage of improved sensitivity scaling, effectively leveraging the temporal dimension to substitute for the spatial resources that would otherwise be required in a massive parallel array.

Interleaved with the encoding steps is the critical operation of applying a control unitary operation (218) to the photonic probe state (212) between passes. This step involves coherently switching the probe state from its current vector configuration to a subsequent one defined by the protocol vector (236), modifying the distribution of photons among the modes without collapsing the superposition or losing the phase information already gathered. Implementation of this coherent mapping may involve complex quantum logic operations, such as CNOT gates in a superconducting circuit architecture, to seamlessly transfer population between Fock states. The benefit of this dynamic reconfiguration is the ability to synthesize an effective Hamiltonian that matches the complex algebraic structure of arbitrary linear functions, enabling optimal sensing of variables that are not naturally coupled to the static eigenstates of the system.

The method also includes detecting the relative phase accumulated on the photonic probe state (212) after the total number of passes. This detection step utilizes high-precision readout hardware, such as photon number resolving detectors performing a parity measurement, to extract the phase signature which encodes the linear function value. By performing the measurement only after the full coherent evolution is complete, the method integrates the information from all passes into a single robust observable. This leads to the ultimate advantage of the invention: the estimation of the linear function with a mean square error that scales as, pushing the performance of the sensor network to the fundamental limits of physical law.

In specific implementations of the method, the step of identifying the set of integer vectors (234) involves a rigorous filtering process that strictly bounds the permissible photon distributions by the total available energy N. Specifically, the vectors are selected such that the 1-norm restricted to the subset of positive modes (206) is exactly equal to the fixed total photon number N, ensuring that the first branch of the superposition always utilizes the maximum available sensitivity for the constructive components of the linear function. Conversely, the 1-norm restricted to the negative modes (208) is constrained to be less than or equal to N, a structural asymmetry that physically accommodates the signed arithmetic of the target function by allowing for an imbalance that is compensated by an auxiliary reference mode. This precise vector selection provides the technical advantage of defining a complete basis of “generalized N00N” configurations that are mathematically guaranteed to support optimal sensing trajectories, thereby eliminating sub-optimal states from the protocol design space.

The calculation of the protocol vector (236) is operationalized by solving a specific linear Diophantine equation Wr=NMα/∥α∥_{1,P}, where the matrix W is composed of the identified integer vectors and α represents the rational coefficients of the linear function. This step mathematically links the discrete physical resources, passes and photon distributions, to the continuous target parameter, ensuring that the cumulative phase evolution of the system is exactly proportional to the quantity of interest. By utilizing an integer linear programming algorithm to solve this equation, the method can optimize the protocol to minimize the total number of passes M required, thereby reducing the total sensing time and minimizing the exposure of the quantum state to decoherence mechanisms. This algorithmic approach provides improved functionality by automating the design of complex sensing sequences that would be intractable to derive manually, ensuring the system operates at the information-theoretic limit of precision.

Regarding the physical instantiation of the probe, the generating step prepares a specific superposition state of the form ω□_{P} [symbol] v0 [symbol] +e^{iφ}v−ω□_{N} [symbol] |N−∥ω|N∥1 [symbol] . In this configuration, the first branch concentrates the photons exclusively in the positive modes (206), while the second branch distributes them among the negative modes (208) and the reference mode (214). This specific state structure is beneficial because it maximizes the variance of the generator of translations with respect to the parameter of interest, a condition necessary for saturating the quantum Cramér-Rao bound. When the sensing protocol concludes, the detection of the relative phase is performed using a photon number resolving detector (230) configured to execute a parity measurement. Parity measurements are particularly advantageous in this context as they provide a signal that oscillates at the Heisenberg limit frequency, allowing for the extraction of phase information with a sensitivity that scales as 1/N, far surpassing the 1/\sqrt{N} scaling of classical intensity measurements.

The method finds particular utility in advanced biological sensing applications, where the set of local physical parameters (204) comprises a distribution of magnetic fluxes and the optical modes (202) are implemented as microwave resonators (224) coupled to a superconducting quantum interference device (SQUID) array (228). In this magnetoencephalography context, the method effectively solves an inverse problem to estimate the location of electrical activity in a biological source, such as the brain, by coherently integrating the flux signals across the sensor array. This arrangement offers enhanced performance in detecting transient neurological events with high spatial resolution while minimizing the magnetic exposure required. Alternatively, in geodesic applications, the local parameters (204) may represent optical path lengths in a network of Mach-Zehnder interferometers (222) modulated by gravitational forces. By measuring the spatial variation of the gravitational field via the linear function, the method enables precise gradient sensing for geophysical exploration.

To implement the sophisticated control required for these protocols, the application of the control unitary operation (218) may utilize a sequence of CNOT operations on a set of superconducting qubits (226) coupled to the optical modes. These gates mediate the non-linear interaction required to map between different Fock state superpositions, providing the coherent control necessary to switch the probe state configuration without collapsing the wavefunction. Finally, the method may involve iterating the entire sequence of generating, encoding, applying, and detecting for a plurality of repetitions. By constructing a statistical estimate from these repeated trials, the system can refine the measurement of the linear function to achieve an asymptotic precision that adheres to the Heisenberg scaling limit, providing a robust and reproducible sensing capability.

The method for configuring a photonic sensor network (200) begins with the physical arranging of a plurality of optical modes (202) to couple with a set of local physical parameters (204), a step that establishes the fundamental interface between the quantum system and the classical environment it interrogates. This arrangement involves the precise topological layout of waveguides, cavities, or free-space paths such that each mode interacts specifically with a distinct local field or force, thereby mapping the spatial distribution of the parameters directly onto the independent degrees of freedom of the electromagnetic field. Crucially, this step includes designating a subset of positive modes (206) and a subset of negative modes (208) corresponding to the signs of the coefficients in the linear function to be estimated; this designation is not merely a labeling exercise but a physical routing decision that determines which modes will be entangled in the constructive versus destructive branches of the probe state superposition. The technical benefit of this structured arrangement is the creation of a hardware-level analogue calculator that inherently processes the signed arithmetic of the sensing task through the interference of quantum amplitudes, reducing the complexity required in post-processing.

Following the layout of the sensing array, the method proceeds to coupling a state preparation assembly (210) to the plurality of optical modes (202). This coupling physically connects the quantum source, whether it be a non-linear crystal assembly for spontaneous parametric down-conversion or a superconducting qubit circuit, to the input ports of the sensor network. The state preparation assembly (210) is specifically adapted to generate a photonic probe state (212) characterized by a fixed total photon number N distributed in a macroscopic superposition between the designated positive modes (206) and negative modes (208). This adaptation ensures that the system is initialized in a state of maximal variance with respect to the target generator, a necessary condition for achieving sub-shot-noise precision. The advantage of this configuration step is the establishment of a resource state that is resilient against common-mode noise while remaining exquisitely sensitive to the differential phase shifts imposed by the parameter function.

The configuration process continues with integrating a control assembly (216) with the plurality of optical modes (202) to govern the time-evolution of the photonic probe state (212). This integration involves embedding active optical components, such as phase modulators or tunable couplers, within the network topology to allow for the dynamic manipulation of the quantum state between sensing passes. By establishing this control infrastructure, the method enables the implementation of sophisticated interrogation protocols that go beyond static measurements, allowing the probe state to traverse a specific trajectory through the Hilbert space that optimizes information gain. The technical effect is the ability to synthesize effective Hamiltonians that are not natively present in the static hardware, thereby expanding the sensing capabilities of the network to include arbitrary linear functions.

A critical algorithmic step in the configuration is programming a memory module within the control assembly (216) with a protocol vector (236) r. This vector is not arbitrary but is rigorously derived from a linear Diophantine equation Wr=NMα/∥α∥_{1,P}, which mathematically relates the available matrix W of integer vectors, representing the set of physically realizable photon distributions, to the vector of rational coefficients α defining the sensing task. Programming this vector effectively compiles the abstract information-theoretic optimal strategy into a concrete machine-readable sequence of operations that the control assembly executes. This ensures that the hardware operations are mathematically guaranteed to accumulate a total phase shift exactly proportional to the quantity of interest, providing the benefit of precision that scales at the Heisenberg limit.

The method also involves connecting a detection assembly (220) to the plurality of optical modes (202) to measure the relative phase accumulated by the photonic probe state (212) after the sequence of operations defined by the protocol vector (236) is complete. This connection aligns the output of the optical paths with high-efficiency readout devices, such as photon number resolving detectors capable of projecting the complex entangled state onto a parity basis. By physically terminating the optical circuit with these specific detectors, the configuration ensures that the phase information, which has been coherently amplified by the multi-pass protocol, can be extracted with maximal fidelity. The ultimate advantage of this manufacturing method is the production of a sensor network that is intrinsically calibrated to solve a specific inverse problem with the minimum possible energy expenditure and maximum possible precision allowed by quantum mechanics.

In various embodiments of the configuration method, the step of arranging the plurality of optical modes (202) specifically entails constructing a network of Mach-Zehnder interferometers (222) wherein the optical path lengths of the constituent arms are modulated by the set of local physical parameters (204). This construction physically embeds the sensing problem into the interference pattern of the network, as the phase shift acquired in each arm is directly proportional to the physical quantity being measured, such as a gravitational force acting on a cantilever mirror or a refractive index change in a sample material. The technical benefit of this interferometric arrangement is the conversion of minute variations in physical parameters into detectable phase shifts that can be coherently amplified through the multi-pass protocol, providing sensitivity to gradients and spatial distributions that exceeds classical limits.

Alternatively, for applications requiring high-sensitivity magnetic field detection, the arranging step comprises fabricating a plurality of microwave resonators (224) on a superconducting circuit substrate, establishing a robust platform for manipulating microwave photons with minimal loss. This fabrication process is further refined by coupling a superconducting quantum interference device (SQUID) array (228) to the plurality of microwave resonators (224), effectively creating a transducer interface that converts a magnetic flux distribution, such as that emanating from a biological source, into the set of local physical parameters (204) manifested as resonance frequency shifts. By integrating SQUIDs, the sensor network is configured to detect weak electromagnetic signals with high spatial resolution, solving the inverse problem of source localization with Heisenberg-limited precision.

To enable the generation of the requisite non-classical states, the coupling of the state preparation assembly (210) involves connecting a superconducting qubit circuit (226) to the plurality of optical modes (202), specifically to mediate the generation of Fock state superpositions via non-linear quantum interactions. This step is crucial because linear optical elements alone cannot deterministically generate the macroscopic superpositions of fixed photon number N required for the optimal probe states; the qubits provide the necessary anharmonicity to prepare states of the form |N [symbol] _{P}|0 [symbol] N+|0 [symbol] _{P}|N [symbol] _{N}. Consequently, this configuration allows the system to initialize the sensing protocol in a regime of maximal quantum fisher information, which is unattainable with classical coherent states.

The configuration of the control infrastructure includes programming the memory module to store a specific sequence of unitary operations (218) that coherently map the photonic probe state (212) between different photon number distributions specified by the matrix W between passes through the plurality of optical modes (202). This programming transforms the control assembly (216) into a dynamic quantum state machine that executes the integer linear programming solution, ensuring that the probe state evolves along the optimal trajectory defined by the protocol vector. Furthermore, the method may involve calibrating the control assembly (216) to apply this sequence of operations at discrete time intervals corresponding to the M passes, synchronizing the state transformations with the physical interaction times of the sensor array.

To optimize physical resource utilization, the method may further comprise assembling an optical switch loop (232) configured to recirculate the photonic probe state (212) through the plurality of optical modes (202) for the number of passes M determined by the 1-norm of the protocol vector (236). This loop architecture eliminates the need for a physically cascaded chain of interferometers, thereby reducing the hardware footprint and minimizing propagation losses while maintaining the requisite number of parameter interactions. Finally, the connecting of the detection assembly (220) involves aligning a photon number resolving detector (230) to the output of the optical modes to enable a high-fidelity parity measurement. This alignment is critical for projecting the complex phase-encoded state onto the measurement basis that saturates the quantum Cramér-Rao bound, ensuring that the information gathered during the coherent evolution is efficiently extracted. In a specific medical application, configuring the photonic sensor network (200) comprises establishing a magnetoencephalography system arranged to solve an inverse problem regarding a location of electrical activity in a brain, leveraging the entanglement-enhanced sensitivity to detect transient neural signals that would be imperceptible to classical magnetometer arrays.

The disclosed technology pertains to a quantum metrology framework specifically engineered for photonic sensor networks to estimate linear functions of unknown parameters with precision scaling at the Heisenberg limit (1/N). Unlike qubit-based systems where sensitivity resources can be deployed in parallel, photonic resources, specifically photon number, must be distributed among sensors. Certain embodiments provide a hardware and control architecture that resolves this limitation by treating the sensing protocol as a dynamic trajectory through a specific subspace of the system's Hilbert space.

The technology relies on the preparation of entangled probe states that are not static but are effectively “generalized N00N states.” These states are macroscopic superpositions where a fixed total photon number N is concentrated entirely in modes contributing positively to the linear function in one branch of the superposition, and entirely in modes contributing negatively (plus a reference mode) in the other branch. A control assembly then actively manipulates these states between passes through the sensor array. By solving a linear Diophantine equation that maps the available photon number distributions (integer vectors) to the desired linear function coefficients (rational numbers), the system derives a control sequence that coherently switches the probe state configuration. This ensures that the accumulated quantum phase is exactly proportional to the target function, enabling optimal readout via parity measurements. Applications range from detecting gravitational gradients with interferometers to mapping neurological activity with magnetoencephalography arrays.

In an embodiment, a magnetoencephalography (MEG) system includes “optical modes” that are microwave resonators interacting with SQUIDs. The “local physical parameters” are magnetic fluxes generated by brain activity. The state preparation uses superconducting qubits to generate the photon-number superpositions. The control assembly applies gates to the qubits to switch the photon distribution among resonators between sensing periods, effectively “scanning” the sensitivity profile of the array to match the inverse problem of source localization.

In an embodiment, a gravitational gradient sensor includes optical modes that are arms of a Mach-Zehnder interferometer network. The parameters are phase shifts induced by gravitational forces on test masses (e.g., cantilevers). The system circulates a pulse of light (the probe state) through the network M times. Between each pass, fast optical switches or modulators re-route the photons to different arms according to the calculated protocol vector, synthesizing a measurement of the gravitational gradient.

In an embodiment, a refractive index mapper includes a sensor network to measure variations in refractive index across a material surface. The positive and negative modes correspond to different spatial regions, allowing the system to directly sense contrasts or gradients in the material properties without reconstructing the absolute index at every point.

While the primary embodiments describe discrete switching between passes, the scope of the invention extends to continuous-time control Hamiltonians where the probe state evolves smoothly through the vector space W, provided the integral of the interaction Hamiltonian satisfies the optimality conditions derived from the Fisher information matrix.

The physical implementation of the reference mode (214) can vary. In configurations where the sum of the positive coefficients equals the sum of the absolute values of the negative coefficients (∥α∥_{1,P}=∥α∥_{1,N}), the reference mode is unnecessary and may be omitted, as the photon number is naturally conserved between the active sensing branches.

Furthermore, while a detection method can be a parity measurement due to its optimality for N00N-like states, alternative detection schemes such as homodyne detection (particularly for displacement sensing variations) or adaptive phase estimation measurements are also contemplated within the scope of the invention, provided they extract the encoded phase information with sufficient Fisher information. The system is agnostic to the specific frequency of the electromagnetic radiation, applicable to optical, microwave, or other bosonic field excitations appropriate for the specific sensing environment.

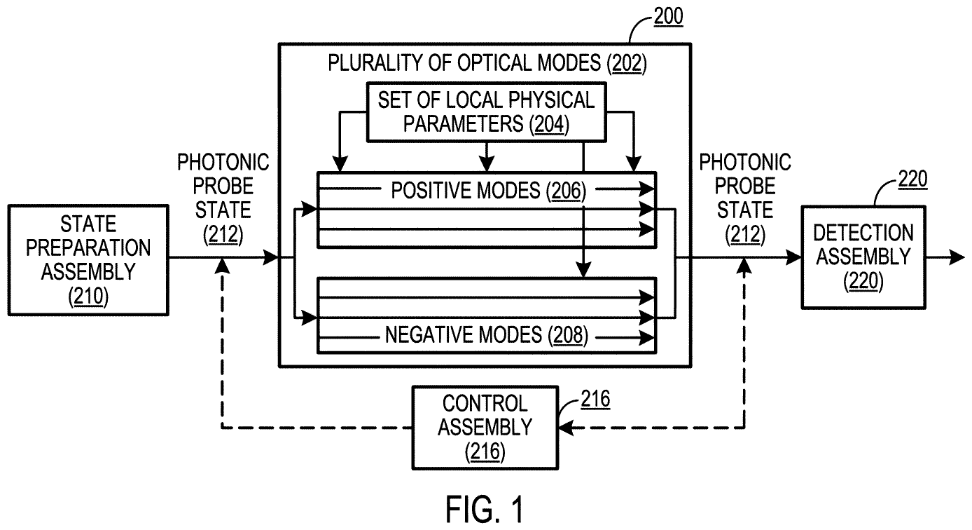

FIG. 1 shows, according to some embodiments, a high-level schematic block diagram of the photonic quantum sensor network 200 arranged to estimate a linear function of spatially distributed physical parameters. The photonic quantum sensor network 200 is depicted as a distributed system comprising a plurality of optical modes 202 that physically traverse a sensing region containing the set of local physical parameters 204. These parameters 204, which may represent scalar quantities such as phase shifts θⱼ or quadrature displacements, are coupled to the optical modes 202 via a specific interaction Hamiltonian, effectively impressing their values onto the quantum state of the light fields. The diagram illustrates the segregation of the plurality of optical modes 202 into distinct subsets based on the mathematical sign of the coefficients in the linear function q(θ)=α·θ to be estimated. A subset of positive modes 206 is shown interacting with the parameters corresponding to positive coefficients αⱼ≥0, while a subset of negative modes 208 interacts with parameters corresponding to negative coefficients αⱼ<0. This architectural division allows the photonic quantum sensor network 200 to structurally embody the arithmetic of the sensing task. The state preparation assembly 210 is illustrated at the input stage, generating the photonic probe state 212 that enters the sensing region. The control assembly 216 is depicted as interacting with the photonic probe state 212 iteratively or sequentially, applying unitary operations 218 to manipulate the state evolution. Finally, the detection assembly 220 is shown at the output, receiving the evolved state to perform the final measurement that yields the estimate of the linear function. The interconnectivity shown in FIG. 1 highlights the flow of quantum information from initialization by the state preparation assembly 210, through the encoding interaction with the local physical parameters 204 and the dynamic modulation by the control assembly 216, to the final readout by the detection assembly 220.

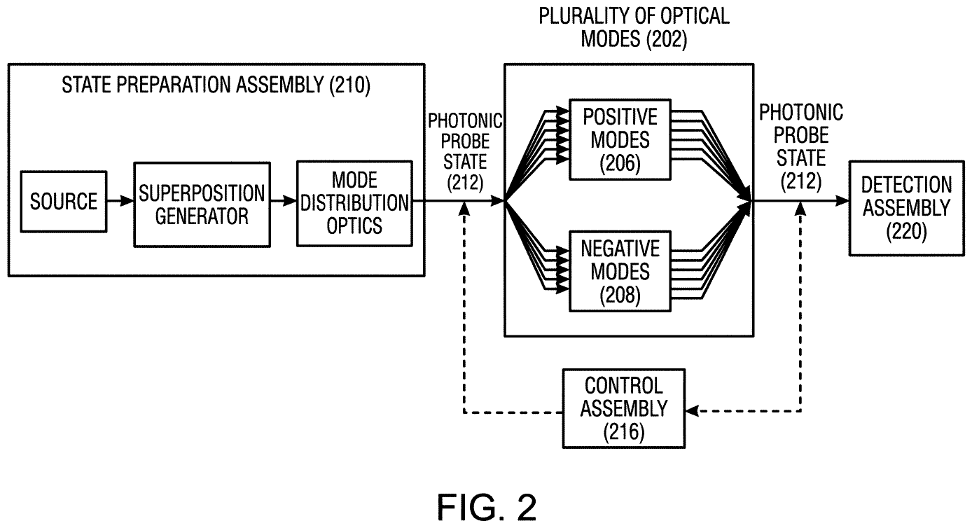

FIG. 2 shows, according to some embodiments, a detailed architectural diagram of the sensor network illustrating the coupling between the state preparation assembly 210, the positive and negative optical modes, the control assembly 216, and the detection assembly 220. The state preparation assembly 210 is shown comprising components adapted to generate a macroscopic superposition state, specifically a “generalized N00N” state. The diagram depicts the photonic probe state 212 as a superposition of two distinct branches, a first branch where the fixed total photon number N is confined entirely within the positive modes 206, and a second branch where the photon number N is distributed among the negative modes 208 and an auxiliary reference mode 214. The reference mode 214 is illustrated as an optical path that does not interact with the set of local physical parameters 204 but serves to balance the photon number conservation constraints when the norms of the positive and negative coefficient vectors differ. The control assembly 216 is integrated into the optical path between passes, illustrated as a sequence of active optical elements or logic gates capable of applying the sequence of unitary operations 218. These operations 218 are depicted as coherent mapping transformations that shuffle the photon distribution among the modes within the respective positive and negative subsets without collapsing the superposition between the branches. The detection assembly 220 includes a photon number resolving detector 230 arranged to measure the parity of the output state, a measurement basis shown to be optimal for extracting the relative phase φtot accumulated between the superposition branches. The layout emphasizes the preservation of coherence throughout the entire optical circuit, ensuring that the final detection event reflects the integrated contributions of all sensing passes.

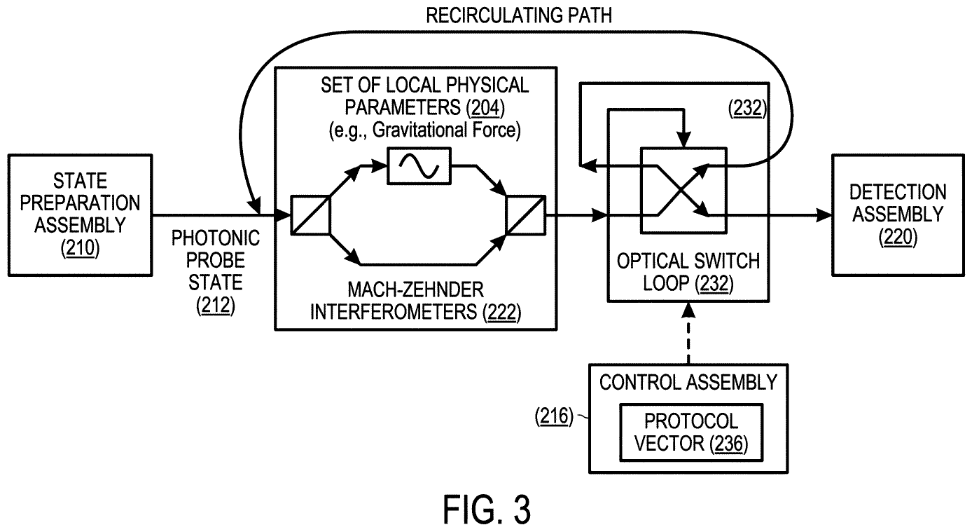

FIG. 3 shows, according to some embodiments, a schematic representation of a specific physical implementation utilizing a network of Mach-Zehnder interferometers 222 to measure optical path length variations. In this embodiment, the plurality of optical modes 202 corresponds to the spatial arms of the Mach-Zehnder interferometers 222. The set of local physical parameters 204 are represented as phase shifts induced by external forces, such as gravitational gradients acting on test masses attached to the interferometer mirrors or cantilevers. The state preparation assembly 210 is depicted as a source of entangled photons, such as a non-linear crystal setup or a cavity QED system, injecting the N00N-like probe state into the interferometer inputs. The control assembly 216 is realized via an optical switch loop 232 that recirculates the light pulses through the interferometers 222. This loop architecture allows the same physical sensors to be interrogated multiple times (M passes), with the control assembly 216 re-routing the photons to different arms or applying phase corrections between passes to execute the optimal protocol vector 236. The detection assembly 220 is shown positioned at the output port of the switch loop 232, capturing the interference pattern resulting from the multi-pass evolution. This specific implementation highlights the utility of the invention in geodesy and high-precision force sensing, where the 1/N² scaling provides a significant advantage over classical interferometric techniques.

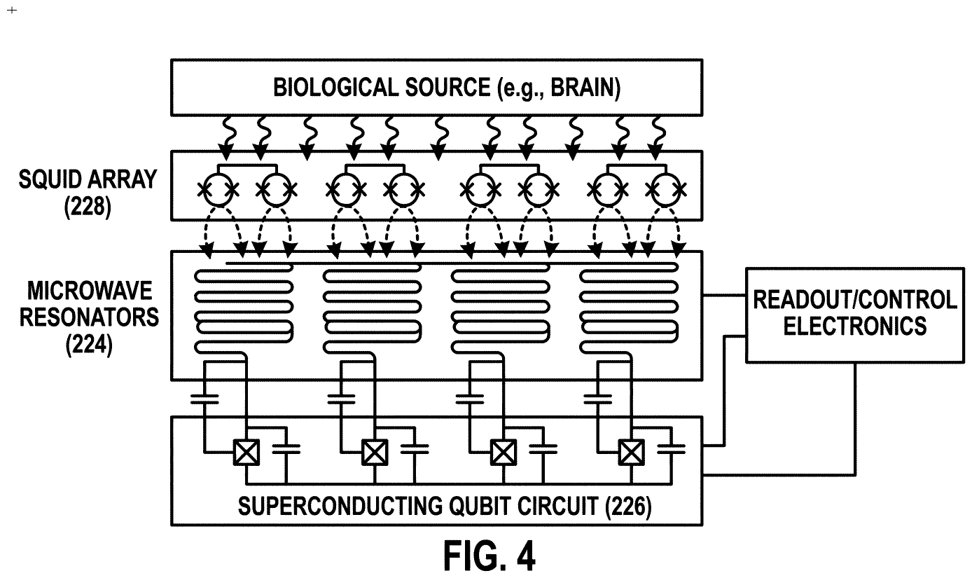

FIG. 4 shows, according to some embodiments, a schematic representation of an alternative physical implementation utilizing a plurality of microwave resonators 224 coupled to a superconducting qubit circuit 226 and a SQUID array 228 for magnetoencephalography applications. Here, the optical modes 202 are microwave cavity modes defined on a superconducting chip. The local physical parameters 204 are magnetic fluxes threading the SQUIDs 228, which modify the resonance frequencies of the microwave resonators 224. The state preparation assembly 210 utilizes the superconducting qubit circuit 226, which is capacitively or inductively coupled to the resonators 224, to synthetically generate the required Fock state superpositions through controlled logic operations. The control assembly 216 is implemented via microwave control lines that drive the qubits 226 to perform CNOT-like operations between sensing intervals, coherently moving the photon population between different resonators 224 according to the optimal protocol. This embodiment illustrates biological sensing, where the system solves the inverse problem of localizing electrical activity in the brain by estimating a linear function of the magnetic flux distribution detected by the SQUID array 228.

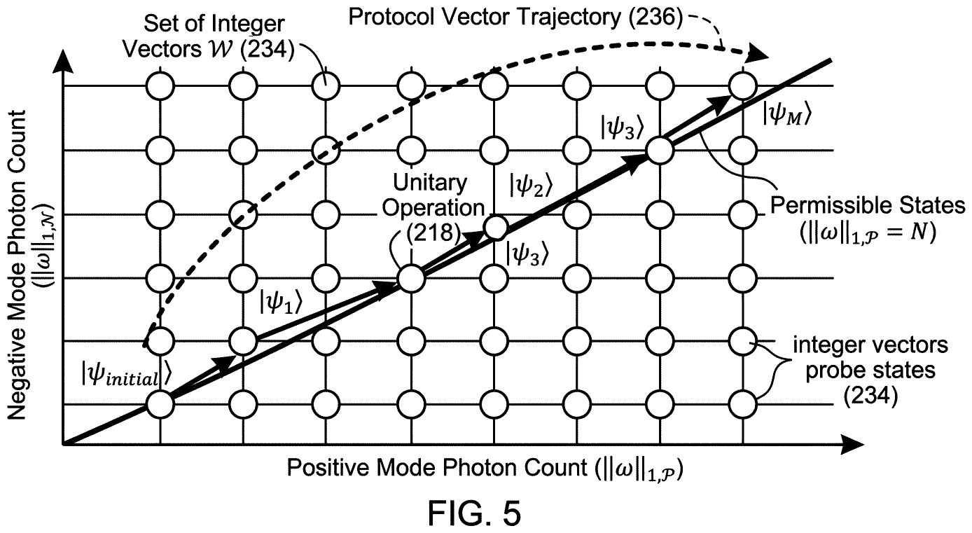

FIG. 5 shows, according to some embodiments, a conceptual diagram illustrating the parameterized families of probe states defined by the set of integer vectors 234 and the coherent mapping trajectories dictated by the protocol vector 236. The diagram visualizes the Hilbert space of the system as a lattice of integer vectors W, where each node represents a valid distribution of the N photons among the positive modes 206 and negative modes 208. The identifying step of the method corresponds to selecting the specific subset of nodes that satisfy the norm constraint ∥ω∥_{1,P}=N. The protocol vector 236 is represented as a directed path or sequence of dwell times on specific nodes within this lattice. The unitary operations 218 performed by the control assembly 216 are depicted as transitions between these nodes, illustrating how the probe state |ψₘ evolves from one vector configuration to another between passes. This visualization clarifies an operational principle, wherein optimal sensing is achieved not by a static state, but by a dynamic trajectory that synthesizes the target Hamiltonian α·ĝ through piecewise interactions defined by the integer solution to the linear Diophantine equation.

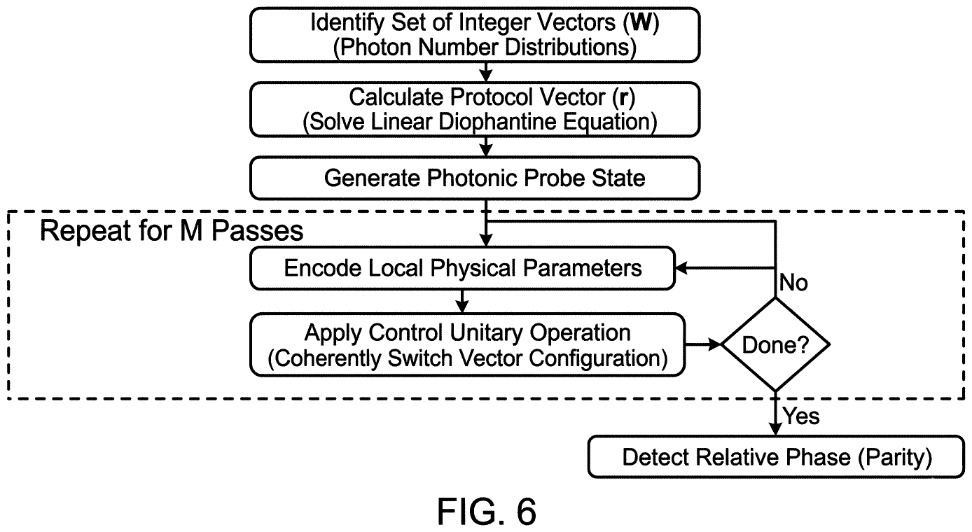

FIG. 6 shows, according to some embodiments, a flowchart illustrating the method for operating the quantum sensor network to solve the linear Diophantine equation and execute the sensing protocol. The flowchart begins with the step of identifying the set of integer vectors W based on the available hardware resources (N photons, d modes). The next block depicts the calculation of the protocol vector r by solving the equation Wr=NMα/∥α∥_{1,P} using an integer linear programming algorithm. Subsequent steps illustrate the physical execution of the protocol that includes: generating the initial probe state, entering a loop where the system encodes parameters via a pass through the sensors, applying the control unitary to switch the vector configuration, and repeating for M iterations. The final step shows the detection of the accumulated phase. This flowchart provides a procedural view, linking the mathematical design phase to the physical run-time operations of the sensor network.

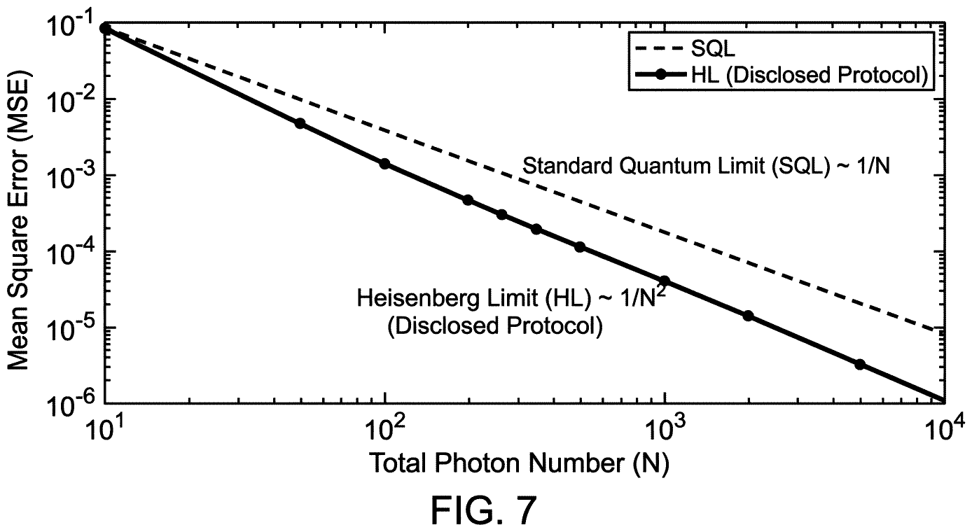

FIG. 7 shows, according to some embodiments, a comparative performance graph plotting the mean square error (MSE) against the total photon number N, demonstrating the Heisenberg scaling advantage of the disclosed protocols over separable bounds. The graph includes a first curve representing the Standard Quantum Limit (SQL), which scales as 1/N (or 1/\sqrt{N} in precision), typically achievable by separable or classical protocols. A second curve represents the Heisenberg Limit, scaling as 1/N² (or 1/N in precision), which is the theoretical lower bound derived in embodiments herein. Data points or a solid line illustrating the expected performance of the disclosed photonic quantum sensor network 200 are shown to align with the Heisenberg Limit curve, showing that the dynamic protocol utilizing the calculated protocol vector 236 should saturate the fundamental quantum bound. This graphical representation underscores the significant technical advantage, e.g., in the regime of large photon numbers where the quadratic improvement in MSE translates to orders of magnitude better precision for the same energy input.

Embodiments can include the properties, functionality, hardware, and process steps described herein and embodied in any of the following non-exhaustive list:
a process (e.g., a computer-implemented method including various steps; or a method carried out by a computer including various steps);
an apparatus, device, or system (e.g., a data processing apparatus, device, or system including means for carrying out such various steps of the process; a data processing apparatus, device, or system including means for carrying out various steps; a data processing apparatus, device, or system including a processor adapted to or configured to perform such various steps of the process);
a computer program product (e.g., a computer program product including instructions which, when the program is executed by a computer, cause the computer to carry out such various steps of the process; a computer program product including instructions which, when the program is executed by a computer, cause the computer to carry out various steps);
computer-readable storage medium or data carrier (e.g., a computer-readable storage medium including instructions which, when executed by a computer, cause the computer to carry out such various steps of the process; a computer-readable storage medium including instructions which, when executed by a computer, cause the computer to carry out various steps; a computer-readable data carrier having stored thereon the computer program product; a data carrier signal carrying the computer program product);
a computer program product including comprising instructions which, when the program is executed by a first computer, cause the first computer to encode data by performing certain steps and to transmit the encoded data to a second computer; or
a computer program product including instructions which, when the program is executed by a second computer, cause the second computer to receive encoded data from a first computer and decode the received data by performing certain steps.

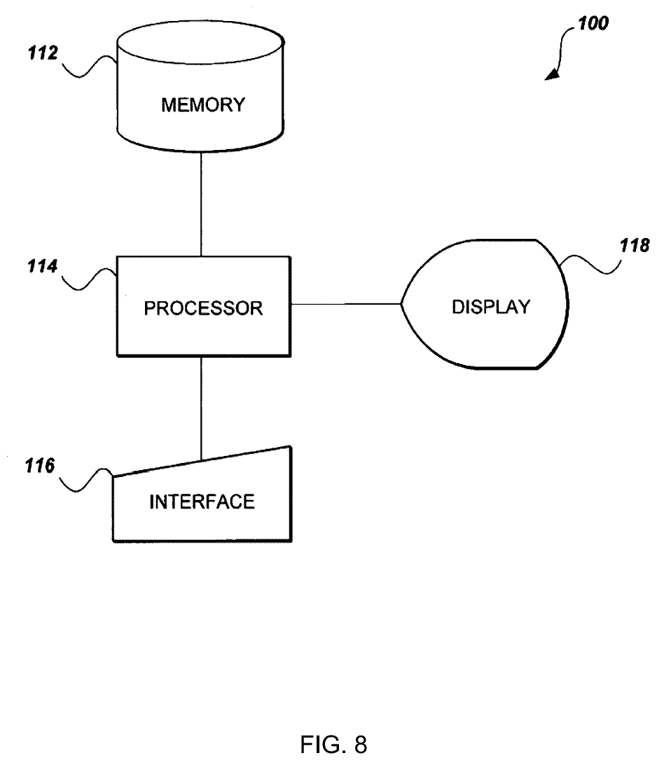

It should be understood that the calculations may be performed by any suitable computer system, such as that diagrammatically shown in the FIG. 8. Data is entered into system 100 via any suitable type of user interface 116, and may be stored in memory 112, which may be any suitable type of computer readable and programmable memory and is preferably a non-transitory, computer readable storage medium. Calculations are performed by processor 114, which may be any suitable type of computer processor and may be displayed to the user on display 118, which may be any suitable type of computer display. Processor 114 may be associated with, or incorporated into, any suitable type of computing device, for example, a personal computer or a programmable logic controller. The display 118, the processor 114, the memory 112 and any associated computer readable recording media are in communication with one another by any suitable type of data bus, as is well known in the art. Examples of computer-readable recording media include non-transitory storage media, a magnetic recording apparatus, an optical disk, a magneto-optical disk, and/or a semiconductor memory (for example, RAM, ROM, etc.). Examples of magnetic recording apparatus that may be used in addition to memory 112, or in place of memory 112, include a hard disk device (HDD), a flexible disk (FD), and a magnetic tape (MT). Examples of the optical disk include a DVD (Digital Versatile Disc), a DVD-RAM, a CD-ROM (Compact Disc-Read Only Memory), and a CD-R (Recordable)/RW. It should be understood that non-transitory computer-readable media include all computer-readable media except for a transitory, propagating signal.

Conventional methodologies for estimating functions of physical parameters via photonic systems predominantly rely on separable probe states or restrict entanglement to the regime of Gaussian states, such as squeezed vacuum, which inherently limits the achievable precision for arbitrary linear combinations of parameters. While these established approaches may offer advantages for specific tasks like displacement sensing under average energy constraints, they often fail to surpass the Standard Quantum Limit when applied to phase sensing problems involving complex linear functions with mixed positive and negative coefficients, as they do not fully exploit the non-classical structure of the Hilbert space available under strict photon number constraints. Furthermore, typical distributed sensing architectures employ static resource allocation, wherein the quantum state is prepared and interrogated without dynamic modification, thereby lacking the temporal flexibility to synthesize optimal measurement operators for functions that do not naturally align with the system's static interaction Hamiltonian.

In contrast, the disclosed technology implements a dynamic sensing protocol that coherently switches the photonic probe state between parameterized families of macroscopic superposition states, specifically “generalized N00N” states, between sequential passes through the sensor array. By governing the time-evolution of the probe according to the integer solution of a linear Diophantine equation derived from the rational coefficients of the target function, the system mathematically guarantees that the total accumulated phase is exactly proportional to the physical quantity of interest. This algebraic configuration enables the measurement precision to scale inversely with the square of the total photon number, the Heisenberg limit, for arbitrary linear functions, a performance characteristic that distinguishes the system from Gaussian-based approaches that typically achieve such scaling only for restricted classes of problems like simple averages. Additionally, the structural segregation of optical modes into positive and negative subsets allows the system to physically encode the signed arithmetic of the estimation task into the quantum interference pattern itself, enabling the direct readout of gradients and weighted sums without the error propagation associated with independent parameter estimation.

The processes described herein may be embodied in, and fully automated via, software code modules executed by a computing system that includes one or more general purpose computers or processors. The code modules may be stored in any type of non-transitory computer-readable medium or other computer storage device. Some or all the methods may alternatively be embodied in specialized computer hardware. In addition, the components referred to herein may be implemented in hardware, software, firmware, or a combination thereof.

Many other variations than those described herein will be apparent from this disclosure. For example, depending on the embodiment, certain acts, events, or functions of any of the algorithms described herein can be performed in a different sequence, can be added, merged, or left out altogether (e.g., not all described acts or events are necessary for the practice of the algorithms). Moreover, in certain embodiments, acts or events can be performed concurrently, e.g., through multi-threaded processing, interrupt processing, or multiple processors or processor cores or on other parallel architectures, rather than sequentially. In addition, different tasks or processes can be performed by different machines and/or computing systems that can function together.

Any logical blocks, modules, and algorithm elements described or used in connection with the embodiments disclosed herein can be implemented as electronic hardware, computer software, or combinations of both. To clearly illustrate this interchangeability of hardware and software, various illustrative components, blocks, modules, and elements have been described above generally in terms of their functionality. Whether such functionality is implemented as hardware or software depends upon the particular application and design constraints imposed on the overall system. The described functionality can be implemented in varying ways for each particular application, but such implementation decisions should not be interpreted as causing a departure from the scope of the disclosure.

The various illustrative logical blocks and modules described or used in connection with the embodiments disclosed herein can be implemented or performed by a machine, such as a processing unit or processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A processor can be a microprocessor, but in the alternative, the processor can be a controller, microcontroller, or state machine, combinations of the same, or the like. A processor can include electrical circuitry configured to process computer-executable instructions. In another embodiment, a processor includes an FPGA or other programmable device that performs logic operations without processing computer-executable instructions. A processor can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor may also include primarily analog components. For example, some or all of the signal processing algorithms described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

The elements of a method, process, or algorithm described in connection with the embodiments disclosed herein can be embodied directly in hardware, in a software module stored in one or more memory devices and executed by one or more processors, or in a combination of the two. A software module can reside in RAM memory, flash memory, ROM memory, EPROM memory, EEPROM memory, registers, hard disk, a removable disk, a CD-ROM, or any other form of non-transitory computer-readable storage medium, media, or physical computer storage known in the art. An example storage medium can be coupled to the processor such that the processor can read information from, and write information to, the storage medium. In the alternative, the storage medium can be integral to the processor. The storage medium can be volatile or nonvolatile.

While one or more embodiments have been shown and described, modifications and substitutions may be made thereto without departing from the spirit and scope of the invention. Accordingly, it is to be understood that the present invention has been described by way of illustrations and not limitation. Embodiments herein can be used independently or can be combined.

All ranges disclosed herein are inclusive of the endpoints, and the endpoints are independently combinable with each other. The ranges are continuous and thus contain every value and subset thereof in the range. Unless otherwise stated or contextually inapplicable, all percentages, when expressing a quantity, are weight percentages. The suffix(s) as used herein is intended to include both the singular and the plural of the term that it modifies, thereby including at least one of that term (e.g., the colorant(s) includes at least one colorants). Option, optional, or optionally means that the subsequently described event or circumstance can or cannot occur, and that the description includes instances where the event occurs and instances where it does not. As used herein, combination is inclusive of blends, mixtures, alloys, reaction products, collection of elements, and the like.

As used herein, a combination thereof refers to a combination comprising at least one of the named constituents, components, compounds, or elements, optionally together with one or more of the same class of constituents, components, compounds, or elements.
All references are incorporated herein by reference.

The use of the terms “a,” “an,” and “the” and similar referents in the context of describing the invention (especially in the context of the following claims) are to be construed to cover both the singular and the plural, unless otherwise indicated herein or clearly contradicted by context. It can further be noted that the terms first, second, primary, secondary, and the like herein do not denote any order, quantity, or importance, but rather are used to distinguish one element from another. It will also be understood that, although the terms first, second, etc. are, in some instances, used herein to describe various elements, these elements should not be limited by these terms. For example, a first current could be termed a second current, and, similarly, a second current could be termed a first current, without departing from the scope of the various described embodiments. The first current and the second current are both currents, but they are not the same condition unless explicitly stated as such.

The modifier about used in connection with a quantity is inclusive of the stated value and has the meaning dictated by the context (e.g., it includes the degree of error associated with measurement of the particular quantity). The conjunction or is used to link objects of a list or alternatives and is not disjunctive; rather the elements can be used separately or can be combined together under appropriate circumstances.

### PARTS LIST

photonic quantum sensor network 200
plurality of optical modes 202
set of local physical parameters 204
positive modes 206
negative modes 208
state preparation assembly 210
photonic probe state 212
reference mode 214
control assembly 216
sequence of unitary operations 218
detection assembly 220
Mach-Zehnder interferometers 222
microwave resonators 224
superconducting qubit circuit 226
superconducting quantum interference device array 228
photon number resolving detector 230
optical switch loop 232
set of integer vectors 234
protocol vector 236

What is claimed is:

1. A photonic quantum sensor network (200) comprising: a plurality of optical modes (202) coupled to a set of local physical parameters (204), wherein the plurality of optical modes (202) includes a subset of positive modes (206) associated with positive coefficients of a linear function and a subset of negative modes (208) associated with negative coefficients of the linear function; a state preparation assembly (210) arranged to generate a photonic probe state (212), wherein the photonic probe state (212) comprises a superposition of a first branch having a fixed total photon number N distributed among the positive modes (206) and zero photons in the negative modes (208), and a second branch having zero photons in the positive modes (206) and the fixed total photon number N distributed among the negative modes (208) and a reference mode (214); a control assembly (216) arranged to apply a sequence of unitary operations (218) to the photonic probe state (212) between a plurality of passes through the plurality of optical modes (202), wherein the control assembly (216) coherently maps the photonic probe state (212) between different vector configurations selected from a set of integer vectors W to preserve a relative phase between the first branch and the second branch; and a detection assembly (220) arranged to measure the relative phase accumulated on the photonic probe state (212) after the plurality of passes.

2. The photonic quantum sensor network (200) of claim 1, wherein the set of integer vectors W comprises vectors ω satisfying a condition ∥ω∥_{1,P}=N and ∥ω∥_{1,N}≤N, wherein P denotes indices of the positive modes (206) and N denotes indices of the negative modes (208).

3. The photonic quantum sensor network (200) of claim 2, wherein the control assembly (216) comprises a memory storing a protocol vector r that satisfies a linear Diophantine equation Wr=NMα/∥α∥_{1,P}, wherein W is a matrix having columns from the set of integer vectors W, M is a total number of the passes, and α is a vector of rational coefficients defining the linear function.

4. The photonic quantum sensor network (200) of claim 1, wherein the photonic probe state (212) generated by the state preparation assembly (210) for a specific integer vector ω corresponds to a superposition form ω□_{P} [symbol] v0 [symbol] +e^{iφ}v−ω□_{N} [symbol] |N−∥ω|N∥1 [symbol] , wherein φ is an arbitrary phase.

5. The photonic quantum sensor network (200) of claim 1, wherein the plurality of optical modes (202) comprises a network of Mach-Zehnder interferometers (222).

6. The photonic quantum sensor network (200) of claim 1, wherein the plurality of optical modes (202) comprises a plurality of microwave resonators (224) and the state preparation assembly (210) comprises a superconducting qubit circuit (226) coupled to the plurality of microwave resonators (224).

7. The photonic quantum sensor network (200) of claim 6, wherein the set of local physical parameters (204) comprises magnetic fluxes generated by electrical activity in a biological source and coupled to the plurality of microwave resonators (224) via a superconducting quantum interference device array (228).

8. The photonic quantum sensor network (200) of claim 1, wherein the control assembly (216) applies the sequence of unitary operations (218) at discrete time intervals corresponding to the plurality of passes.

9. The photonic quantum sensor network (200) of claim 1, wherein the detection assembly (220) comprises a photon number resolving detector (230) arranged to perform a parity measurement on the photonic probe state (212).

10. The photonic quantum sensor network (200) of claim 1, wherein the control assembly (216) comprises an optical switch loop (232) arranged to recirculate the photonic probe state (212) through the plurality of optical modes (202) for the plurality of passes.

11. A method for operating a quantum sensor network (200) to estimate a linear function of a set of local physical parameters (204), the method comprising: identifying a set of integer vectors (234) W, wherein each vector ω in the set of integer vectors (234) defines a photon number distribution satisfying a norm constraint relative to a fixed total photon number N distributed across a plurality of optical modes (202); calculating a protocol vector (236) r comprising non-negative integers that satisfy a linear Diophantine equation relating a matrix W formed from the set of integer vectors (234) to a vector of rational coefficients α representing the linear function; generating a photonic probe state (212) initialized in a superposition of a first branch and a second branch according to a first vector selected from the set of integer vectors (234); encoding the set of local physical parameters (204) into the photonic probe state (212) by subjecting the photonic probe state (212) to a sequence of passes through the plurality of optical modes (202); applying a control unitary operation (218) to the photonic probe state (212) between the passes to coherently switch the photonic probe state (212) from the first vector to a subsequent vector selected from the set of integer vectors (234) based on the protocol vector (236), wherein the control unitary operation (218) maintains the relative phase between the first branch and the second branch; and detecting the relative phase accumulated on the photonic probe state (212) after a total number of passes M defined by the protocol vector (236).

12. The method of claim 11, wherein the identifying the set of integer vectors (234) comprises selecting vectors ω such that a 1-norm of ω restricted to a set of positive modes (206) equals the fixed total photon number N, and a 1-norm of ω restricted to a set of negative modes (208) is less than or equal to the fixed total photon number N.

13. The method of claim 11, wherein the calculating the protocol vector (236) comprises solving the linear Diophantine equation Wr=NMα/∥α∥_{1,P}, wherein ∥α∥_{1,P} is a 1-norm of the vector of rational coefficients restricted to positive coefficients.

14. The method of claim 11, wherein the generating the photonic probe state (212) comprises preparing a superposition state of the form ω□_{P} [symbol] v0 [symbol] +e^{iφ}v−ω□_{N} [symbol] |N−∥ω|N∥1 [symbol] , wherein the first branch comprises photons in positive modes (206) and the second branch comprises photons in negative modes (208) and a reference mode (214).

15. The method of claim 11, wherein the detecting the relative phase comprises performing a parity measurement on the photonic probe state (212) using a photon number resolving detector (230) coupled to the plurality of optical modes (202).

16. The method of claim 11, wherein the set of local physical parameters (204) comprises a distribution of magnetic fluxes, and the plurality of optical modes (202) comprises microwave resonators (224) coupled to a superconducting quantum interference device array (228), and wherein the method estimates a location of electrical activity in a biological source.

17. The method of claim 11, wherein the set of local physical parameters (204) comprises optical path lengths in a network of Mach-Zehnder interferometers (222), and wherein the method measures a spatial variation of a gravitational field acting on the network.

18. The method of claim 11, wherein the applying the control unitary operation (218) utilizes a sequence of CNOT operations on a set of superconducting qubits (226) coupled to the plurality of optical modes (202) to map between Fock state superpositions.

19. The method of claim 11, further comprising iterating the generating, encoding, applying, and detecting steps for a plurality of repetitions to construct a statistical estimate of the linear function achieving a Heisenberg scaling precision limit.

20. The method of claim 11, wherein the calculating the protocol vector (236) utilizes an integer linear programming algorithm to minimize the total number of passes M required to satisfy the linear Diophantine equation.
